(19) United States
(12) Patent Application Publication
(10) Pub. No.: US 2023/0138498 A1
(43) Pub. Date: May 4, 2023

(54) AUDIO RECORDING METHOD AND ASSOCIATED AUDIO PROCESSING CIRCUIT

(71) Applicant: SigmaStar Technology Ltd., Fuijan (CN)

(72) Inventors: Chun-Nan LU, Zhubei City (TW); Chun-Chia CHANG, Zhubei City (TW); Ko-Fang WANG, Zhubei City (TW)

(21) Appl. No.: 17/735,270

(22) Filed: May 3, 2022

(30) Foreign Application Priority Data
Nov. 2, 2021 (CN) 202111288635.2

(51) Int. Cl. G11B 20/10

(52) U.S. Cl. CPC G11B 20/10527; G11B 20/10037; G11B 2020/10546

(57) ABSTRACT

The present invention provides an audio recording method and an associated audio processing circuit. The recording method includes performing an initialization of an audio processing circuit at a first timing, setting a gain of the audio processing circuit to a first value at a second timing, using the audio processing circuit to start recording at a third timing, completing the initialization of the audio processing circuit at a fourth timing, and adjusting the gain of the audio processing circuit to a second value at a fifth timing. The second value is greater than the first value, the first timing and the second timing are earlier than the third timing, the fourth timing is later than the third timing, and the fifth timing is later than the third timing.

This application claims the benefit of China application Serial No. CN202111288635.2, filed on Nov. 2, 2021, the subject matter of which is incorporated herein by reference.

### BACKGROUND OF THE INVENTION

### Field of the Invention

The present invention relates to audio recording control, and more particularly, to an audio recording method and an associated audio processing circuit.

### Description of the Related Art

In the prior art, a portable audio recording device can be used for audio recording in various occasions. However, certain issues may occur. For example, when a user controls the portable audio recording device to start recording, the user needs to wait for the portable audio recording device to enter an operating state, and this causes a waste of time of the user. In the prior art, some suggestions have been proposed in attempt to solve the issue above, with however certain potential additional side-effects incurred. For example, noise produced in the event of improper control may be recorded in an audio file recorded. Therefore, there is a need for a novel method and associated architecture, so as to implement a compact and reliable audio recording device without bringing side-effects or less likely incurring side-effects.

### SUMMARY OF THE INVENTION

It is an object of the present invention to provide an audio recording method and an associated audio processing circuit so as to solve the issue above.

An audio recording method is provided according to an embodiment of the present invention. The audio recording method is applied to an electronic device that includes an audio processing circuit. The audio recording method includes performing an initialization of an audio processing circuit at a first timing, setting a gain of the audio processing circuit to a first value at a second timing, using the audio processing circuit to start recording at a third timing, completing the initialization of the audio processing circuit at a fourth timing, and adjusting the gain of the audio processing circuit to a second value at a fifth timing. The second value is greater than the first value, the first timing and the second timing are earlier than the third timing, the fourth timing is later than the third timing, and the fifth timing is later than the third timing.

An audio processing circuit for operating the audio recording method above is further provided according to another embodiment of the present invention. The audio processing circuit includes at least one amplifier, at least one analog-to-digital converter (ADC) coupled to the at least one amplifier, and a processor coupled to the at least one ADC. For example, the at least one amplifier may be used to adjust a gain of at least one audio signal to generate at least one adjusted audio signal, the at least one ADC may be used to perform analog-to-digital conversion on the at least one adjusted audio signal to generate at least one digital audio signal, and the processor may be used to control an operation of the audio processing circuit and perform audio processing on audio samples carried in the at least one digital audio signal.

One benefit of the present invention is that, with the carefully designed control mechanism, the audio recording method and the audio processing circuit of the present invention are capable of properly managing scheduling of associated settings before and after audio recording. Compared to the prior art, the audio recording method and the audio processing circuit of the present invention are capable of implementing a compact and reliable audio recording device without bringing side-effects or less likely incurring side-effects.

### BRIEF DESCRIPTION OF THE DRAWINGS

To better describe the technical solution of the embodiments of the present application, drawings involved in the description of the embodiments are introduced below. It is apparent that, the drawings in the description below represent merely some embodiments of the present application, and other drawings apart from these drawings may also be obtained by a person skilled in the art without involving inventive skills.

FIG. 1 is a schematic diagram of an electronic device according to an embodiment of the present invention;

FIG. 2 is a flowchart of an audio recording method according to an embodiment of the present invention, wherein the audio recording method is applied to an electronic device such as that shown in FIG. 1;

FIG. 3 is a setting control solution of the audio recording method shown in FIG. 2 according to an embodiment of the present invention;

FIG. 4 is an example of an audio waveform in conditions without using the audio recording method; and

FIG. 5 is an example of an audio waveform in conditions with the audio recording method used.

### DETAILED DESCRIPTION OF THE INVENTION

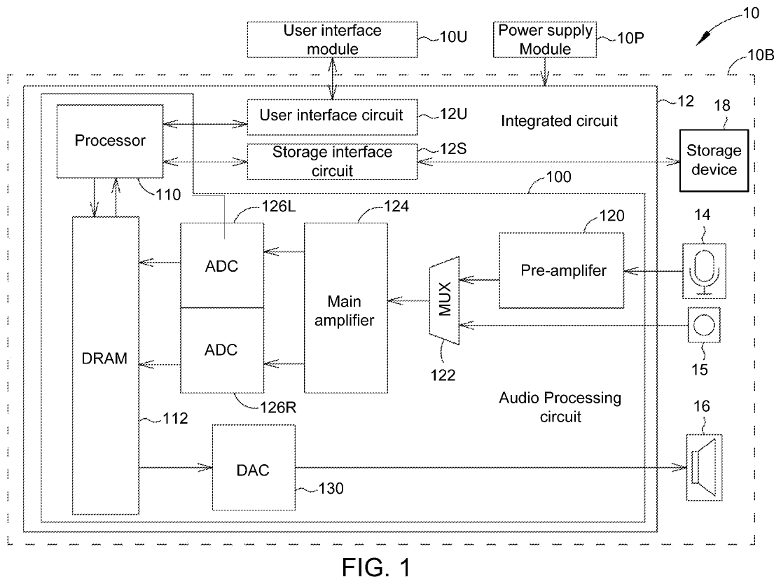

FIG. 1 shows a schematic diagram of an electronic device 10 according to an embodiment of the present invention. The electronic device 10 may include multiple elements such as a user interface module 10U, a power supply module 10P, an integrated circuit 12, a microphone 14, an audio input port 15, a speaker 16 and a storage device 18. At least a part of the elements above, such as the integrated circuit 12, the microphone 14, the audio input port 15, the speaker 16 and the storage device 18, may be mounted on a main circuit board 10B of the electronic device 10; however, the present invention is not limited to the example above. In some embodiments, all of the elements above may be mounted on the main circuit board 10B. Besides, the electronic device 10 may be, for example but not limited to, a camera, a portable audio recording device, a wearable device or a multi-function mobile phone.

As shown in FIG. 1, the integrated circuit 12 may include an audio processing circuit 100, a user interface circuit 12U and a storage interface circuit 12S. The audio processing circuit 100 may include a processor 110, a dynamic random access memory (DRAM) 112, at least one amplifier such as a pre-amplifier 120 and a main amplifier 124, a multiplexer 122 (denoted as MUX for brevity), at least one analog-to-digital converter (ADC) such as multiple ADCs 126L and 126R, and a digital-to-analog converter (DAC) 130; however, the present invention is not limited to the example above. For example, one or more buses may be configured in the architecture shown in FIG. 1, so as to allow related elements therein to be coupled to one another.

The user interface module 10U may include at least one user input device (not shown) for receiving a user input, and may include a display device (not shown) for displaying information for notifying a user. For example, the at least one user input device may be implemented by such as a touch panel or a button, and the display device may be implemented by such as a display panel. In some examples, the touch panel and the display panel are integrated into one touch sensitive display device, such as a touch screen. Moreover, the power supply module 10P can power other elements in the electronic device 10, for example, the integrated circuit 12 and sub-circuits therein, and some elements coupled to the integrated circuit 12. The microphone 14 may receive audio waves for the electronic device 10 (for example, the audio processing circuit 100) to generate one or more audio signals, and more particularly, may be implemented as a stereo microphone to generate a first set of audio signals corresponding to a left audio channel and a right audio channel. The audio input port 15 may be used to couple the electronic device 10 (for example, the audio processing circuit 100) to an audio source device (not shown) outside the electronic device 10, so as to receive a second set of audio signals from the audio source device. The storage device 18 may be used to store multiple audio files such as multiple recorded audio files for the electronic device 10 (for example, the audio processing circuit 100), wherein the audio processing circuit 100 may perform an audio recording operation according to the first set of audio signals or the second set of audio signals so as to generate multiple audio files. For example, the storage device 18 may be implemented by a non-volatile memory such as a flash memory. Moreover, the speaker 16 may be used to play any of the multiple audio files for the electronic device 10 (for example, the audio processing circuit 100), and more particularly, receiving at least one audio output signal corresponding to any of the audio files for the audio processing circuit 100 (for example, the DAC 130) so as to output audio waves for the user to listen to.

In the integrated circuit 12, the user interface circuit 12U may be used to couple the user interface module 10U to the audio processing circuit 100, and to perform signal conversion between the audio processing circuit 100 and the user interface module 10U so as to allow the user to interact with the electronic device 10 through the user interface circuit 12U. The storage interface circuit 12S may be used to couple the storage device 18 to the audio processing circuit 100, and to perform signal conversion between the audio processing circuit 100 and the storage device 18 so as to allow the audio processing circuit 100 to store files such as the multiple audio files using the storage device 18. Further, the audio processing circuit 100 may be used to perform audio processing; however, the present invention is not limited to the examples above. As shown in FIG. 1, the audio processing circuit 100 includes core elements of the electronic device 10, such as the processor 110 and the DRAM 112, and the processor 110 (for example, a program module operating thereon) may be used to control operations of the electronic device 10.

For audio processing, the at least one amplifier (for example, the pre-amplifier 120 and the main amplifier 124) above may be used to adjust a gain of at least one audio signal to generate at least one adjusted audio signal. More particularly, the pre-amplifier 120 may adjust the gain of the first set of audio signals to generate a set of adjusted audio signals corresponding to the first set of audio signals as a first adjusted version of the first set of audio signals. In addition, when the multiplexer circuit 122 selects and outputs the first adjusted version of the first set of audio signals, the main amplifier 124 may adjust a gain of the first adjusted version of the first set of audio signals to generate another set of adjusted audio signals, which may be regarded as a second adjusted version of the first set of audio signals, wherein the another set of adjusted signals may serve as an example of the at least one adjusted audio signal; however, the present invention is not limited to the examples above. When the multiplexer circuit 122 selects and outputs the second set of audio signals, the main amplifier 124 may adjust a gain of the second set of audio signals to generate a set of adjusted audio signals corresponding to the second set of audio signals, wherein this set of adjusted signals may also serve as an example of the at least one adjusted audio signal. Moreover, the at least one ADC (for example, the ADCs 126L and 126R) may be used to perform analog-to-digital conversion on the at least one adjusted audio signal to generate at least one digital audio signal. When either set of audio signals (for example, each set of audio signals) between the first set of audio signals and the second set of audio signals are stereo audio signals, the ADC 126L may perform analog-to-digital conversion on a first adjusted audio signal corresponding to the left audio channel between the either set of the audio signals to generate a first digital audio signal corresponding to the left audio channel, and the ADC 126R may perform analog-to-digital conversion on a second adjusted audio signal corresponding to the right audio channel between the either set of audio signals to generate a second digital audio signal corresponding to the right audio channel. Further, the processor 110 may be used to control operations of the audio processing circuit 100, and perform audio processing according to audio samples carried in the at least one digital audio signal (for example, the first digital audio signal and the second digital audio signal).

According to some embodiments, the main amplifier 124 may be implemented as a stereo boost amplifier.

According to some embodiments, the speaker 16 may be replaced by an audio output port (not shown in FIG. 1), and the audio output port may be used to couple the electronic device 10 (for example, the audio processing circuit 100) to an audio output device outside the electronic device 10, for example, earphones, an external speaker or a sound system.

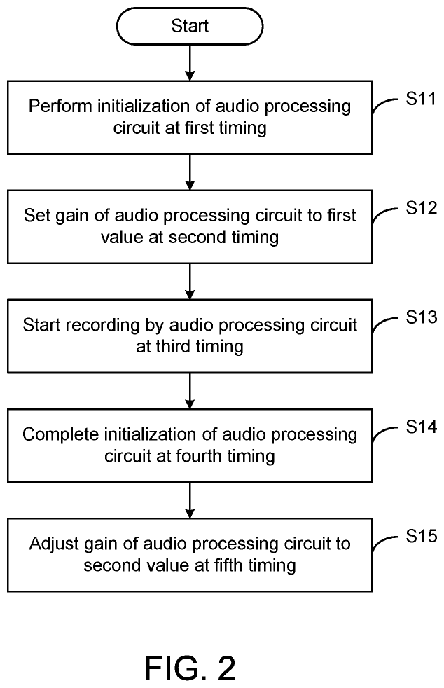

FIG. 2 shows a flowchart of an audio recording method according to an embodiment of the present invention, wherein the audio recording method is applied to such as the electronic device 10 shown in FIG. 1, and more particularly, the audio processing circuit 100, and the audio processing circuit 100 may be operated according to the audio recording method.

In step S11, the audio processing circuit 100 may be initialized at a first timing.

In step S12, the audio processing circuit 100 may set a gain to a first value at a second timing. For example, the gain is an analog gain, and more particularly, the first value of the analog gain that is a settable minimum value; however, the present invention not limited to the example above. For another example, the gain is a digital gain, and more particularly, the first value of the digital gain that is a settable minimum value.

In step S13, after the first timing and the second timing, the audio processing circuit 100 may start recording at a third timing, and more particularly, in order to start recording early, recording may start when the initialization is started but not yet finished. Assuming that the gain is not set in step S12, a pop sound will be produced upon the start of recording. As shown in FIG. 2, since the gain is set in advance by the audio processing circuit 100 in step S12, the audio processing circuit 100 can start recording early without producing any pop sound, so as to save time for the user.

In step S14, the initialization of the audio processing circuit 100 is completed at a fourth timing.

In step S15, the audio processing circuit 100 may adjust the gain to a second value at a fifth timing, wherein the second value is greater than the first value.

According to the embodiment, the first timing and the second timing are earlier than the third timing, the fourth timing is later than the third timing, and the fifth timing is later than the third timing. Moreover, the initialization may include enabling the at least one ADC (for example, the ADCs 126L and 126R), for example, turning on at least one switch (not shown) of the audio processing circuit 100 so as to start powering the at least one ADC. More particularly, when the gain is the analog gain, the analog gain may represent the at least one amplifier (for example, the pre-amplifier 120 and the main amplifier 124); however, the present invention is not limited to the example above. For example, the audio processing circuit 100 may include a digital signal processing (DSP) circuit. The above core elements of the electronic device 10 may be the DSP circuit, which may include the processor 110 and the DRAM 112. When the gain is the digital gain, the digital gain may represent a gain of digital audio processing performed by the DSP circuit (for example, the processor 110).

The operation process shown in FIG. 2 is described to provide better understanding; however, the present invention is not limited to the example. According to some embodiments, one or more steps may be added to the operation process in FIG. 2.

According to some embodiments, the initialization may include configuring multiple hardware parameters stored in multiple storage units in the audio processing circuit 100, wherein the multiple hardware parameters may include the value of the gain. For brevity, similar details in these embodiments are not repeated.

According to some embodiments, the initialization of the audio processing circuit 100 is a first-stage initialization, and initialization of system program codes executed in the processor 110 of the audio processing circuit 100 is a second-stage initialization. The audio recording method may further include setting the gain of the digital audio processing performed by the processor 110 executing the system program codes to zero. For example, the second-stage initialization may further include gradually increasing the gain of the digital audio processing from zero by the audio processing circuit 100.

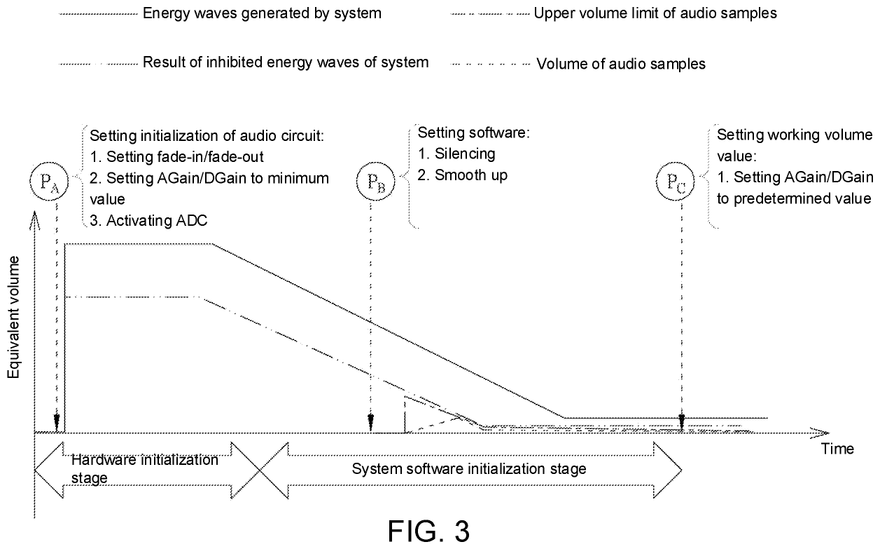

FIG. 3 shows a setting control solution of the audio recording method shown in FIG. 2 according to an embodiment of the present invention. For better understanding, energy waves (for example, noise generated by the entire system architecture not yet reaching a stable state during a boot process) generated by the system may be recorded in a recorded audio file and may thus be represented by an equivalent volume, wherein the horizontal axis represents time and the vertical axis represent the equivalent volume. Moreover, an analog gain AGain and a digital gain DGain may be regarded as examples of the analog gain and the digital gain above. The audio processing circuit 100 may perform at least a part of a first set of audio processing operations, a second set of audio processing operations and a third set of audio processing operations corresponding to timings P_{A}, P_{B} and P_{C}, respectively; for example, any one, any two or all sets of the audio processing operations of the three sets. Preferably, the audio processing circuit 100 may at least perform the first set of audio processing operations corresponding to the timing P_{A}.

During a hardware initialization stage, for example, at the timing P_{A}, the audio processing circuit 100 may perform audio circuit initialization setting to inhibit energy waves generated by the system, wherein the audio circuit initialization setting may include the first set of audio processing operations:

1. setting fade-in/fade-out; for example, configuring hardware parameters associated with fade-in and fade-out among the multiple hardware parameters;

2. decreasing the analog gain AGain and/or the digital gain DGain; for example, setting to a minimum value; for example, configuring hardware parameters associated with the gain among the multiple hardware parameters, such as the analog gain AGain and the digital gain DGain; and

3. activating the at least one ADC (for example, the ADCs 126L and 126R); however, the present invention is not limited to the examples above. As shown in FIG. 3, a result of the inhibited energy waves of the system may also be represented by an equivalent volume, and is typically smaller than energy waves generated by the system in conditions without performing the audio circuit initialization setting.

During a system software initialization stage, for example, at the timing P_{B}, the audio processing circuit 100 may perform software setting so as to ensure overall performance of the audio processing, wherein the software setting may include the second set of audio processing operations:

1. silencing; for example, forcibly turning off any possible volume, and more particularly, keeping the analog gain AGain and/or the digital gain DGain at a lower value, for example, a minimum value; and

2. smooth up, wherein the gain is, for example, increasing the digital gain DGain by a fixed value within unit time;

however, the present invention is not limited to the examples above. As shown in FIG. 3, an upper volume limit of the audio samples does not exceed the result of inhibited energy waves of the system. Within a period from the timing P_{B} to before the audio samples are generated, the upper volume limit of the audio samples is typically equal to zero, and this is because no audio samples exist within this period. Further, the volume of the audio samples does not exceed the upper volume limit of the audio samples, and may be gradually increased along with the smooth up. The smooth up can prevent sounds that suddenly appear from being recorded when recording normally starts after audio has been silenced, hence bringing better user experience. In one embodiment, the audio processing circuit 100 can calculate the audio samples in this stage according to a proportion, and more particularly, adjusting proportion of audio samples with predefined unit point (for example, data point) by gradually increasing a proportion parameter PROPORTION for calculating the volume, so as to slowly amplifying the audio samples from a small volume to an actual volume value (in this case, the proportion reaches 100%). For example, the audio processing circuit 100 may gradually increase the volume value by means of adjusting the proportion by equations EQU(1) and EQU(2), thereby preventing a pop sound caused by a few of overly large volume value, as the following:

Val_{new}=Val_{old}*PROPORTION>>15 EQU(1)

PROPORTION+=PROPORTION_ step_ size EQU(2).

In the equations above, “Val_{new}” and “Val_{old}” respectively represent a new gain and an old gain, “>>” represents a bitwise right shift operation (for example, performing a bit shift operation in a direction toward the least significant bit (LSB) to reduce the value), and “+=” represents an addition assignment operation (for example, adding two values respectively on the left and right of “+=” to provide the latest values of the values on the left of “+=”). Equation EQU(1) is for controlling the size of the new gain Val_{new} according to the old gain Val_{old}, and equation EQU(2) is for controlling the proportion parameter PROPORTION through the step size PROPORTION_ step_ size of the proportion parameter PROPORTION to control the increment each time the latest gain (for example, the new gain Val_{new} in equation EQU(1)) is calculated. According to equation EQU(2), the audio processing circuit 100 may gradually increase the proportion exhibited by (PROPORTION>>15) in equation EQU(1), for example, gradually increasing from a minimum value 0.003% to a maximum value such as 100%, so as to control the size of the new gain Val_{new}.

Taking a unit point of 8 for example, the step size PROPORTION_ step_size of the proportion parameter PROPORTION may be set to 1; in addition, taking the current proportion parameter PROPORTION rising up to 16 for example, the audio samples included in each audio chunk is divided in to sets each containing eight data points, and calculation is performed on multiple sets (eight data points in each set) of these audio chunks. When the current proportion parameter PORPORTION is 16, the audio samples produced by this set in this stage may be equal to the original audio samples within this set multiplied by the current value (for example, 16) of the proportion parameter PROPORTION, and the bit is shifted to the right, wherein the amount of shifting the bit to the right may be equal to 15 bits. Then, the next set of proportion parameter PROPORTION to use may be equal to the sum (for example, 17) of the previous value of the proportion parameter PROPORTION (for example, 16) added by a predetermined increment such as the step size PROPORTION_ step_size (for example, 1). Next, the audio processing circuit 100 may perform the similar operation on eight data points of the next set, until each data point of this audio chunk has undergone the proportion calculation and converted into the volume adjustment result of the smooth up.

After the system software initialization stage, for example, at the timing P_{C}, the audio processing circuit 100 may set a working recording volume to ensure that an audio recording operation can be normally performed, wherein the setting of the working recording volume may include the third set of audio processing operations:

1. increasing the analog gain AGain and/or the digital gain DGain to a predetermined value (for example, a predetermined value based on a predetermined setting or user-setting, and is typically non-zero); however, present invention is not limited to the example above. After a predetermined time has elapsed from the audio processing circuit 100 completes the hardware initialization and the electronic device 10 has not yet completed the software initialization, the audio processing circuit 100 may set the gain (for example, the analog gain AGain and/or the digital gain DGain) to a predetermined value, and more particularly, setting the analog gain AGain and/or the digital gain DGain to a predetermined value (for example, a predetermined value based on a predetermined setting or user-setting).

It should be noted that, the configuration of the audio processing circuit 100 for the timing (the third timing) at which recording starts is very flexible. For example, the initialization in step S11 may include the hardware initialization, the first timing may represent a certain timing before the timing P_{A}, and the second timing may represent the timing P_{A}. In this case, the audio processing circuit 100 may be configured to start recording after the timing P_{A} (for example, the third timing may be after the timing P_{A}). Since the audio processing circuit 100 already decreased the analog gain AGain and/or the digital gain DGain at the timing P_{A}, the audio processing circuit 100 may start recording before the initialization is complete. As shown in FIG. 3, since the audio processing circuit 100 may set the gain in advance in step S12, and more particularly, decreasing the analog gain AGain and/or the digital gain DGain at the timing P_{A}, the audio processing circuit 100 can start recording early without producing any pop sound, so as to save time for the user.

For another example, the initialization in in step S11 may include the system software initialization, the first timing may represent a certain timing (for example, a start timing of the system software initialization) before the timing P_{B}, and the second timing may represent the timing P_{B}. In this case, the audio processing circuit 100 may be configured to start recording after the timing P_{B} (for example, the third timing may be after the timing P_{B}), and more particularly, may be configured to start recording at a timing between the timings P_{B} and P_{C} (for example, the third timing may be between the timings P_{B} and P_{C}). Since the audio processing circuit 100 already performed silencing at the timing P_{B}, for example, forcibly turning off all any possible volume, and more particularly, keeping the analog gain AGain and/or the digital gain DGain to a low value, the audio processing circuit 100 may start recording before the initialization is completed. As shown in FIG. 3, the audio processing circuit 100 may set the gain in advance in step S12, and more particularly, keeping the analog gain AGain and/or the digital gain DGain at a minimum value at the timing P_{B}.

For another example, the initialization in step S11 may include the first-stage initialization such as a hardware initialization, and more particularly, further including the subsequent second-stage initialization such as a system software initialization, the first timing may represent a certain timing before the timing P_{A}, and the second timing may represent the timing P_{A}. In this case, the audio processing circuit 100 may be configured to start recording after the timing P_{A} (for example, the third timing may be after the timing P_{A}), and more particularly, may be configured to start recording at a timing between the timings P_{A} and P_{C} (for example, the third timing may be between the timings P_{A} and P_{C}). Since the audio processing circuit 100 already decreased the analog gain AGain and/or the digital gain DGain at the timing P_{A}, and the audio processing circuit 100 already performed silencing at the timing P_{B}, the audio processing circuit 100 may start recording early without producing a pop sound.

For better understanding, the four curves shown in FIG. 3 depict respective trends of energy waves generated by the system, a result of inhibited energy waves of the system, an upper volume limit of audio samples, and a volume size of the audio samples; however, the present invention is not limited to the examples above. According to some embodiments, the four curves may be modified. For example, the smooth up performed by the audio processing circuit 100 can prevent sounds that suddenly appear from being recorded when recording normally starts after audio has been silenced, hence bringing better user experience. Regardless of which timing between the timings P_{B} and P_{C} (for example, a timing at which the curve of the upper volume limit of indicated audio samples becomes non-zero after the timing P_{B}) the third timing is, the volume of the audio samples can gradually increase along with the smooth up operation, wherein the curve of the upper volume limit of the indicated audio samples can be correspondingly adjusted. For example, as shown in FIG. 3, the curve of the upper limit volume of indicated audio samples starts rising upon encountering a volume curve of indicated audio samples becomes gradually rising, so as to tolerate the volume curve of indicated audio samples to continue rising, and more particularly, rising by a proportion shown by (PROPORTIONAL>>15) in equation EQU(1) of the smooth up.

As shown in FIG. 3, the timing P_{B} may be depicted as being before the timing P_{C}; however, the present invention is not limited to the example above. According to some embodiments, the timing P_{B} may be shifted to the right, or may be shifted to the right to behind the timing P_{C}.

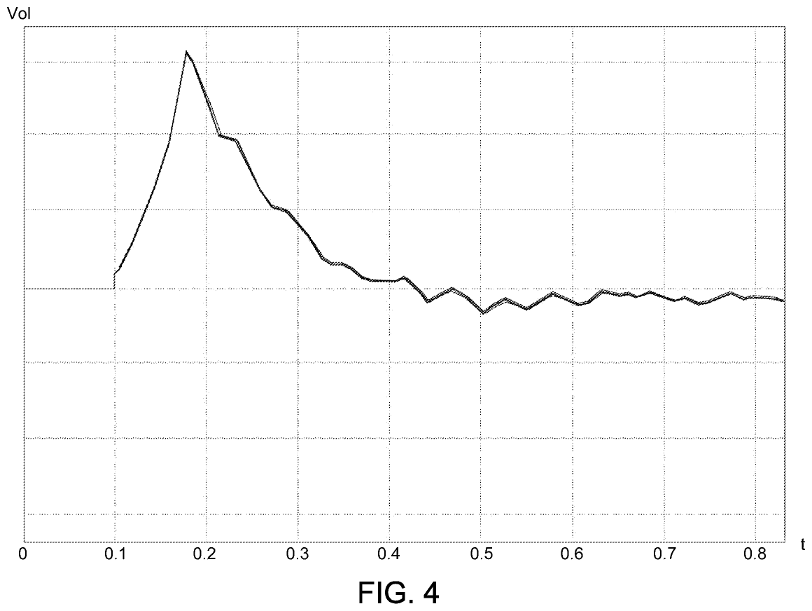

FIG. 4 shows an example of an audio waveform in conditions without using the audio recording method, wherein the horizontal axis and the vertical axis respectively represent time and equivalent volume (respectively indicated as “t” and “Vol” for simplicity). In conditions without using the audio recording method, the energy waves generated by the system is recorded in a recorded file. Because the hardware of the overall system has not yet reached a stable state, and noise such as energy waves generated by the system is recorded in the recorded file, a user may hear a short pop sound (for example, a buzz-like sound that exhibits a short surge on the waveform of a sound track) while listening to the recorded file. If the user is currently using a sound system for audio playback, a sharp pop sound may be suddenly produced, and this could bring an extremely undesirable user experience.

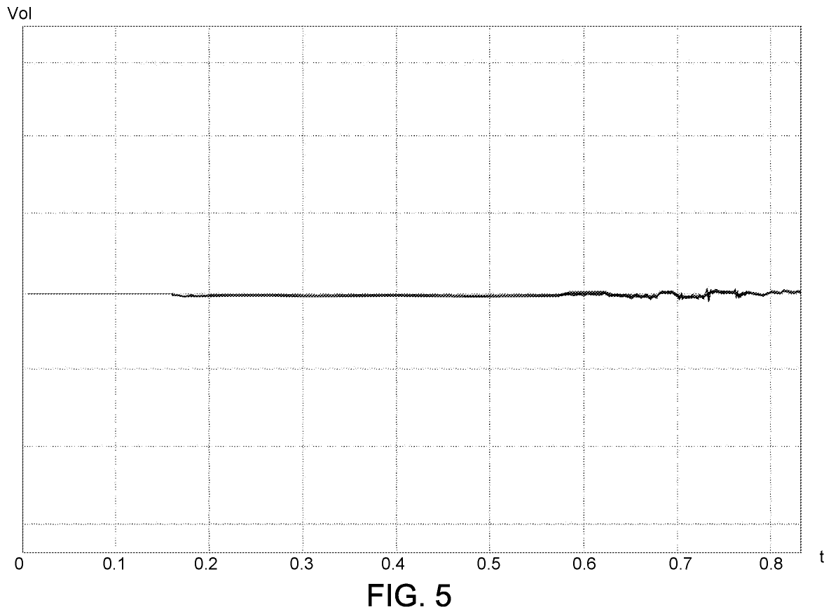

FIG. 5 shows an example of an audio waveform in conditions with the audio recording method used, wherein the horizontal axis and the vertical axis respectively represent time and equivalent volume (respectively indicated as “t” and “Vol” for simplicity). Compared to the audio waveform in FIG. 4, the audio waveform of this example appears quite moderate. In conditions with the audio recording method used, energy waves generated by the system are suppressed, the upper volume limit of the audio samples does not exceed a result of the suppressed energy waves of the system, and the volume of the audio samples does not exceed an upper volume limit of the audio samples, and therefore the energy waves generated by the system are not recorded in the recorded file. More particularly, the volume of the audio samples may gradually increase along with the smooth up operation instead of suddenly increasing to a predetermined volume, further enhancing user experience.

One benefit of the present invention is that, with the carefully designed control mechanism, the audio recording method, the audio processing circuit 100, the integrated circuit 12 and the electronic device 10 are capable of properly managing scheduling of associated settings before and after audio recording. Compared to the prior art, the audio recording method, the audio processing circuit 100, the integrated circuit 12 and the electronic device 10 of the present invention are capable of implementing a compact and reliable audio recording device without bringing side-effects or less likely incurring side-effects.

The description above provides merely preferred embodiments of the present invention, and all variations and modifications made based on the range of claims of the present invention are to be encompassed within the scope of the present invention.

What is claimed is:

1. An audio recording method, applied to an electronic device that comprises an audio processing circuit, the audio recording method comprising:
performing an initialization of the audio processing circuit at a first timing;
setting a gain of the audio processing circuit to a first value at a second timing;
starting recording using the audio processing circuit at a third timing;
completing the initialization of the audio processing circuit at a fourth timing; and
adjusting the gain of the audio processing circuit to a second value at a fifth timing;
wherein, the second value is greater than the first value, the first timing and the second timing are earlier than the third timing, the fourth timing is later than the third timing, and the fifth timing is later than the third timing.

2. The audio recording method of claim 1, wherein the gain is an analog gain.

3. The audio recording method of claim 2, wherein the analog gain is a settable minimum value.

4. The audio recording method of claim 1, wherein the gain is a digital gain.

5. The audio recording method of claim 4, wherein the digital gain is a settable minimum value.

6. The audio recording method of claim 1, wherein the audio processing circuit comprises at least one analog-to-digital converter (ADC), and the initialization further comprises activating the at least one ADC.

7. The audio recording method of claim 2, wherein the audio processing circuit comprises at least one amplifier, and the analog gain represents a gain of the at least one amplifier.

8. The audio recording method of claim 4, wherein the audio processing circuit comprises a digital signal processing (DSP) circuit, and the digital gain represents a gain of digital audio processing performed by the DSP circuit.

9. The audio recording method of claim 1, wherein the initialization comprises configuring a plurality of hardware parameters stored in a plurality of storage units in the audio processing circuit, and the hardware parameters comprise a value of the gain.

10. The audio recording method of claim 1, wherein the gain is an increment within unit time.

11. The audio recording method of claim 1, further comprising:
after a predetermined period has elapsed from the audio processing circuit completes a hardware initialization and the electronic device has not yet completed a software initialization, setting the gain to a predetermined value.

12. The audio recording method of claim 1, wherein the initialization of the audio processing circuit is a first-stage initialization, and an initialization of system program codes executed in a processor of the audio processing circuit is a second-stage initialization; the audio recording method further comprises:
setting the gain of the digital audio processing performed by the processor executing the system program codes to zero.

13. The audio recording method of claim 12, wherein the second-stage initialization further comprises gradually increasing the gain of the digital audio processing from zero by the audio processing circuit.

14. The audio processing circuit operated according to the audio recording method of claim 1, wherein the audio processing circuit comprises:
at least one amplifier, for adjusting a gain of at least one audio signal to generate at least one adjusted audio signal;
at least one analog-to-digital converter (ADC), coupled to the at least one amplifier, for performing analog-to-digital conversion on the at least one adjusted audio signal to generate at least one digital audio signal; and
a processor, coupled to the at least one ADC, for controlling an operation of the audio processing circuit, and performing audio processing according to audio samples carried in the at least one digital audio signal.
